(19) United States
(12) Patent Application Publication
(10) Pub. No.: US 2015/0205021 A1
(43) Pub. Date: Jul. 23, 2015

(54) METAMATERIAL FOR IMPROVED ENERGY EFFICIENCY

(71) Applicants: PC Krause and Associates, Inc., West Lafayette, IN (US); Board of Regents, The University of Texas System, Austin, TX (US)

(72) Inventors: John R. Howell, Austin, TX (US); Alex Heltzel, Austin, TX (US); Tyler Pearce Mann, Austin, TX (US)

(21) Appl. No.: 14/600,793

(22) Filed: Jan. 20, 2015

Related U.S. Application Data
(60) Provisional application No. 61/929,349, filed on Jan. 20, 2014.

(51) Int. Cl. G02B 5/28; G02B 1/00; G02B 5/00; C23C 16/06

(52) U.S. Cl. CPC G02B 5/282; C23C 16/06; G02B 1/002; G02B 5/008; Y10S 977/834; B82Y 20/00

(57) ABSTRACT

The present invention includes a variable emissivity metamaterial comprising a substrate and one or more arrays of nanostructured objects deposited on the substrate, wherein the objects comprise a material that has near-IR reflectivity and near-IR absorptivity and the one or more arrays are positioned between 5 and 750 nM from the substrate.

### CROSS-REFERENCE TO RELATED APPLICATIONS

This application claims the benefit of and incorporates by reference herein the disclosure of U.S. Ser. No. 61/929,349, filed Jan. 20, 2014.

### STATEMENT OF FEDERALLY FUNDED RESEARCH

This invention was made with U.S. Government support by NSF Grant No. CBET 1032415, and NASA Grant No. PCK-UTA2012NNX39P. The government has certain rights in this invention.

### TECHNICAL FIELD OF THE INVENTION

The present invention relates in general to the field of energy efficiency, and more particularly, to new metamaterials for improved energy efficiency.

### BACKGROUND OF THE INVENTION

Without limiting the scope of the invention, its background is described in connection with glass substrates.

U.S. Pat. No. 7,082,260, issued to Longobardo, et al., entitled “Apparatus and method for bending and/or tempering glass” is directed to an apparatus and method for bending and/or tempering glass substrate(s). The amount of near-IR radiation that reaches the glass to be bent and/or tempered is limited (e.g., via filtering or any other suitable technique), thus, the IR radiation (used for heating the glass) which reaches the glass to be bent and/or tempered includes mostly mid-IR and/or far-IR radiation, and not much near-IR. In such a manner, coating(s) provided on the glass can be protected and kept at lower temperatures so as to be less likely to be damaged during the bending and/or tempering process. Heating efficiency can be improved. A ceramic (e.g., aluminosilicate) filter or baffle may be used in certain embodiments in order to reduce the amount of mid-IR and/or far-IR radiation reaching the glass to be tempered and/or bent.

United States Patent Publication No. 2008/0237181, filed by Wagner, et al., is entitled, “Hybrid layers for use in coatings on electronic devices or other articles”, and is directed to a method for forming a coating over a surface. Briefly, the method is said to include depositing over a surface a hybrid layer of a mixture of a polymeric material and a non-polymeric material. The hybrid layer may have a single phase or comprise multiple phases. The hybrid layer is formed by chemical vapor deposition using a single source of precursor material. The chemical vapor deposition process may be plasma-enhanced and may be performed using a reactant gas. The precursor material may be an organo-silicon compound, such as a siloxane. The hybrid layer may comprise various types of polymeric materials, such as silicone polymers, and various types of non-polymeric materials, such as silicon oxides. By varying the reaction conditions, the wt % ratio of polymeric material to non-polymeric material may be adjusted. The hybrid layer may have various characteristics suitable for use with organic light-emitting devices, such as optical transparency, impermeability, and/or flexibility.

### SUMMARY OF THE INVENTION

In one embodiment, the present invention includes a variable emissivity metamaterial comprising: a substrate; a surface plasmon-generating layer on the substrate; a dielectric layer on the surface plasmon-generating layer; and one or more arrays of nanostructured objects deposited on the dielectric layer, wherein the objects comprise a material that has near-IR reflectivity and near-IR absorptivity and the one or more arrays are positioned between 5 and 750 nM from the substrate. In one aspect, the objects are triangular, square, rectangular, pentagonal, hexagonal, heptagonal, octagonal, polygonal, trapezoid, striated, lines, irregular, circular, conical, or oval. In another aspect, the material is at least one of silver, copper, gold, tungsten, titanium, tantalum, aluminum, or platinum. In another aspect, the array is regular, periodic, irregular, or variable. In another aspect, the array comprises one or more unit cells of objects. In another aspect, the array is regular, checkerboard, irregular, or variable. In another aspect, the variable emissivity metamaterial is disposed on one or more surfaces of the substrate. In another aspect, the substrate is at least one of glass, fused silica glass, soda-lime-silica glass, borosilicate glass, lead-oxide glass, aluminosilicate glass, oxide glass, ceramic, polarized glass, plastic, polycarbonate, polyacrylate, cellulose acetate, butyrate, nylon, polyolefin, polyester, polyurethane, para-aramid synthetic fiber, or mixtures thereof. In another aspect, the metamaterial further comprises a passivation layer disposed on the array. In another aspect, the one or more arrays are printed on a film, paint, or coating and the film paint, or coating is attached to the substrate. In another aspect, the array is positioned at 5, 6, 7, 8, 9, 10, 11, 12, 13, 14, 15, 16, 17, 18, 19, 20, 21, 22, 23, 24, 25, 26, 27, 28, 29, 30, 35, 40, 45, 50, 60, 70, 75, 80, 90, 100, 125, 150, 200, 250, 300, 350, 400, 450, 500, 550, 600, 650, or 700 nm from the substrate. In another aspect, the array is embedded in a film or coating. In another aspect, the array separated from the substrate by a dielectric.

Another embodiment of the present invention includes a method of variable emissivity metamaterial comprising: obtaining a substrate; depositing a surface plasmon-generating layer on the substrate; placing a dielectric layer on the surface plasmon-generating layer; and placing on the dielectric layer one or more arrays of nanostructured objects at between 5 and 750 nM from the dielectric layer, wherein the objects comprise a material that has near-IR reflectivity and near-IR absorptivity. In one aspect, the objects are triangular, square, rectangular, pentagonal, hexagonal, heptagonal, octagonal, polygonal, trapezoid, striated, lines, irregular, circular, conical, or oval. In another aspect, the material is at least one of silver, copper, gold, tungsten, titanium, tantalum, aluminum, or platinum. In another aspect, the array is regular, checkerboard, irregular, or variable. In another aspect, the array comprises one or more unit cells of objects. In another aspect, the array is regular, periodic, irregular, or variable. In another aspect, the variable emissivity metamaterial is disposed on one or more surfaces of the substrate. In another aspect, the substrate is at least one of glass, fused silica glass, soda-lime-silica glass, borosilicate glass, lead-oxide glass, aluminosilicate glass, oxide glass, ceramic, polarized glass, plastic, polycarbonate, polyacrylate, cellulose acetate, butyrate, nylon, polyolefin, polyester, polyurethane, para-aramid synthetic fiber, or mixtures thereof. In another aspect, the method further comprises a passivation layer disposed on the array. In another aspect, the one or more arrays are printed on a film, paint, or coating and the film paint, or coating is attached to the substrate. In another aspect, the method further comprises the step of optimizing the array and distance between the array and the substrate for at least one of total energy absorbed, optical quality, tint or coloration. In another aspect, the array is positioned at 5, 6, 7, 8, 9, 10, 11, 12, 13, 14, 15, 16, 17, 18, 19, 20, 21, 22, 23, 24, 25, 26, 27, 28, 29, 30, 35, 40, 45, 50, 60, 70, 75, 80, 90, 100, 125, 150, 200, 250, 300, 350, 400, 450, 500, 550, 600, 650, or 700 nm from the substrate. In another aspect, the method further comprises the step of embedding the one or more arrays in a film or coating.

Yet another embodiment of the present invention includes a variable emissivity metamaterial film comprising an array of nanostructured objects, wherein the objects comprise a material that has near-IR reflectivity and near-IR absorptivity. In another aspect, the film is provided in rolls to retrofit existing substrates.

Yet another embodiment of the present invention includes a window comprising: a glass substrate on a reversible frame; a surface plasmon-generating layer on the substrate; a dielectric layer on the surface plasmon-generating layer; and an array of nanostructured objects deposited on the dielectric layer, wherein the objects comprise a material that has near-IR reflectivity and near-IR absorptivity.

Yet another embodiment of the present invention includes a coating comprising an array of nanostructured objects deposited on a dielectric layer, wherein the objects comprise a material that has near-IR reflectivity and near-IR absorptivity.

### BRIEF DESCRIPTION OF THE DRAWINGS

For a more complete understanding of the features and advantages of the present invention, reference is now made to the detailed description of the invention along with the accompanying figures and in which:

FIGS. 1A and 1B show the solar interaction with (a) bare glass, and (b) Ag coated glass (low-∈ window) of the prior art.

FIG. 2 shows the FDTD simulation results, illustrating IR-reflective property of standard 5 nm and 10 nm Ag films, as shown in FIG. 1B.

FIGS. 3A and 3B show the metamaterial (MTM) window glass concept with an MTM layer 30 nm from the surface (3A), and 750 nm (3B) from the surface of the substrate.

FIGS. 4A and 4B show the EM field intensity with MTM layer 30 nm from Ag surface (4A), 750 nm from Ag surface (4B) as shown in FIGS. 3A and 3B, respectively.

FIG. 5 shows the spectral reflectivity comparison of standard, low-∈, and metamaterial window configurations.

FIG. 6 is a graph that shows the ASTM Solar Reference Spectra, Direct and Circumsolar.

FIGS. 7A and 7B show two examples of the metamaterial of the present invention shown in the Summer (7A) configuration and the Winter (7B) configuration.

FIG. 8 is a graph of the reflected radiant intensity as function of wavelength for low-∈ and MTM glass configurations.

FIG. 9 shows the electric field distribution in MTM glass of the present invention in a summer orientation (top) and a winter orientation (bottom), λ=800 nm.

FIG. 10 is a graph that shows the reflected radiant intensity as function of wavelength for low-∈ and MTM glass configurations.

FIG. 11 is a graph that shows the energy capture as a function of MTM coverage of the Ag base layer (constant MTM square width).

FIG. 12 is a graph that shows the energy capture as a function of MTM coverage of Ag base layer (constant MTM period dimension).

FIG. 13 is a graph that shows the absorption shift as a function of MTM spacing.

FIG. 14 shows a Navier-Stokes/Energy simulation of a small, windowed structure in a cold environment.

FIG. 15 shows temperature distributions in wall and glass segments, traditional double-pane window (left), and the MTM window glass (right) of the present invention.

### DETAILED DESCRIPTION OF THE INVENTION

While the making and using of various embodiments of the present invention are discussed in detail below, it should be appreciated that the present invention provides many applicable inventive concepts that can be embodied in a wide variety of specific contexts. The specific embodiments discussed herein are merely illustrative of specific ways to make and use the invention and do not delimit the scope of the invention.

To facilitate the understanding of this invention, a number of terms are defined below. Terms defined herein have meanings as commonly understood by a person of ordinary skill in the areas relevant to the present invention. Terms such as “a”, “an” and “the” are not intended to refer to only a singular entity, but include the general class of which a specific example may be used for illustration. The terminology herein is used to describe specific embodiments of the invention, but their usage does not delimit the invention, except as outlined in the claims.

As used herein, the term “substrate” or “translucent substrate”, refer to any material that is transparent, substantially translucent, or at least partially see-through that includes but is not limited to glass, plastic, polymers, or other materials such as, e.g., glass, fused silica glass, soda-lime-silica glass, borosilicate glass, lead-oxide glass, aluminosilicate glass, aluminosilicate glass, oxide glass, ceramic, polarized glass, plastic, polycarbonate, polyacrylate, cellulose acetate, butyrate, nylon, polyolefin, polyester, polyurethane, para-aramid synthetic fiber, or mixtures thereof.

The design of materials for radiant characteristics often takes into account the spectral dependence in radiative absorption and emission. For instance, natural gas storage tanks are universally painted a shade of white, meant to minimize absorptivity in the visible spectrum during the day, yet maximize emission in the infrared during the night. Positive and negative photoresists are used in combination with a single wavelength of light to produce lithographic effects, and photovoltaic cells are engineered to maximize absorption near the bandgap energies of the semiconductors used. Radiative material properties are famously sensitive, however, and in some cases ill-defined, often providing sub-optimal application. Further, the most recent decade of research has revealed additional strong dependencies of radiative properties in the near-field, in which bulk properties can be dramatically different based on surface structuring at the micro- and nano-scale [1-8]. This sensitivity is a double-edged sword, creating a difficult challenge for analytical or computational design of a nanostructured surface. Several recent communications have demonstrated the ability to manipulate the near-field radiative properties of surfaces and meet demands for specialized applications [9-12].

The present inventors have developed new methods and structures to identify precise, coherent properties for materials that manage radiative energy in intelligent ways. A large fraction of fossil fuel use is dedicated to heating and cooling structures due to seasonal and geographic variations in solar irradiation. The present inventors have now recognized that radiative characteristics of common building materials represent a fulcrum through which the energy efficiency of a structure can be leveraged. The present invention includes designs with novel, intelligent radiative properties using window glass as an example, allowing a structure to absorb or reflect near-infrared energy to adapt to the needs of the interior. The variable emissive properties substantially enhance the thermal efficiency of windowed structures. The present inventors have converged on a design for metamaterial (MTM) window glass with the capability of reducing winter heating demand by over 150 Watts per square meter of installed material. This efficiency gain—relative to current high efficiency, low-emissivity windows—creates significant long-term cost-savings and reduction in fossil fuel usage for medium- to large-sized structures.

Other examples of uses for the materials of the present invention include those in which other types of radiative energy needs to be managed, e.g., cryo-storage tanks, partially-transparent or opaque glass (e.g., oven windows, bullet proof glass), and other non-solar applications. MTM glass can also be used to reduce the heating/cooling demands in vehicles with MTM windows and/or windshields or film layers installed. Vehicles relying solely on electric power for heat generation (or reduced cooling needs) will obtain increased range and the ability to satisfy other electrical demands.

The present inventors used simulations to variably access a large portion of the near-infrared spectrum using a nanoscale base layer of Ag (currently used in low-∈ window glass) with an additional, patterned, Ag layer to create a periodic, metamaterial configuration. For example, MTM window glass is capable of reflecting the near-infrared and far-infrared energy from the sun in its “summer” configuration, yet selectively absorbing solar near-infrared energy in the “winter” configuration. By tuning the radiative properties to this specific wavelength band, the MTM glass retains its ability to reflect far-infrared energy (λ>1500 nm) emitted by heated interior spaces, thereby maximizing the energy efficiency of the window through intelligent design. It is shown herein that the effect is significant, representing an improvement in thermal efficiency enhancement for any windowed or other structure. Based on the present disclosure, the skilled artisan will recognize (as shown herein below) that diurnal variations/angle of incidence can also be determined to more fully evaluate the energy savings of the present invention.

Design and Methodology. Commercially available, high-efficiency, low-emissivity window glass was simulated for algorithm verification and baseline comparison to MTM glass. The finite-difference time domain (FDTD) method solves Maxwell's curl equations at the nodes of a discretized spatial grid [15]. A commercial-grade simulator was used for the investigation, which employs the Yee algorithm to solve for both electric and magnetic field components in time and space [16]. Absorbing, periodic, and Bloch-type boundary conditions are used to simulate macroscale surfaces with small, periodic domains. Grid independence investigations determined minimum spatial resolution for accuracy, which ranged from 2.5 Angstroms to ˜5 nm.

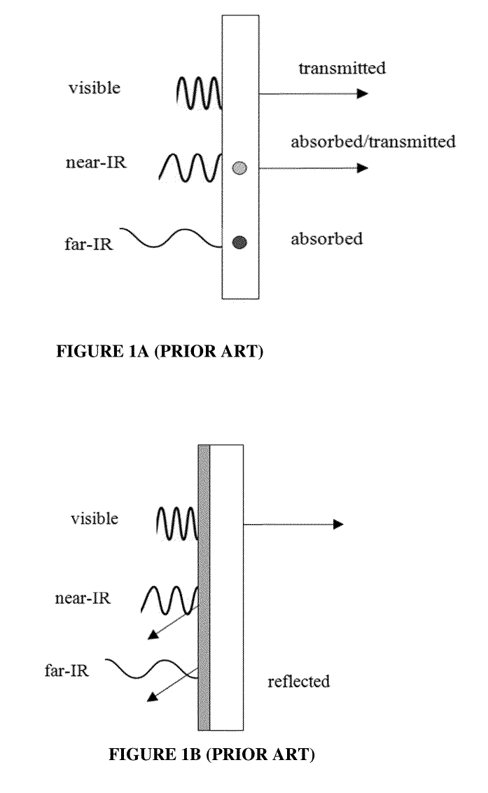

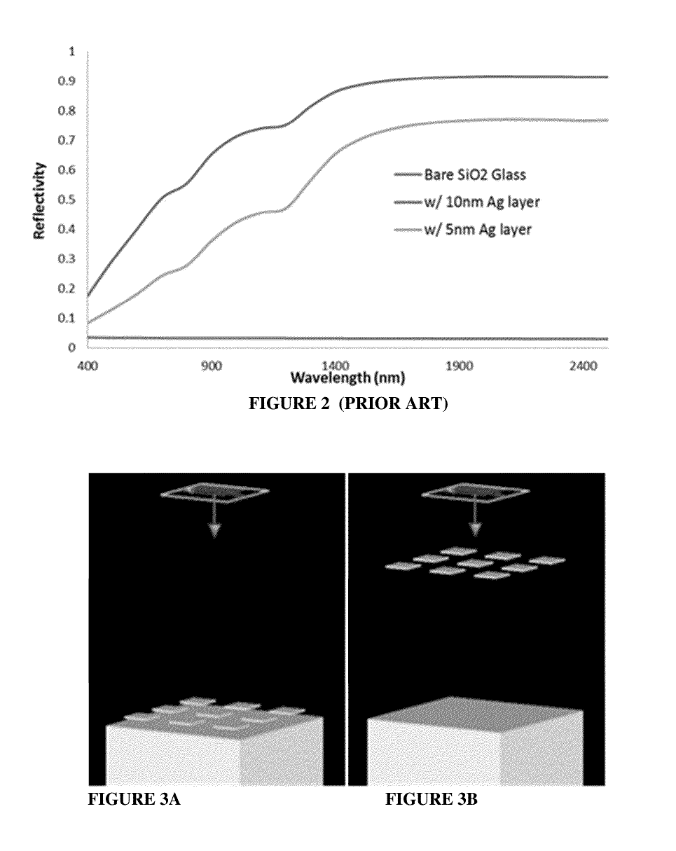

FDTD simulations established baseline configurations for both standard and low-emissivity glass. FIGS. 1A and 1B provide a graphical schematic of standard window glass and commercial low-emissivity glass of the prior art, illustrating the mechanism of IR reflection that boosts energy efficiency in the structure. While standard (bare) glass windows (FIG. 1A) allow virtually all optical wavelengths and a portion of near-infrared solar energy to enter the structure, a significant portion of near- and far-infrared energy is absorbed by the window glass, which is opaque at longer wavelengths. Low-emissivity windows make use of the highly reflective properties of silver to reflect much of the non-optical, unwanted energy during mild or warm periods (FIG. 1B). Chemical vapor deposition (CVD) techniques are typically used to apply ˜5-20 nm of silver in a uniform, thin film. The optical absorption/reflection of the thin-film is minimal, allowing the windows to appear transparent, however the Ag layer efficiently reflects near- and far-IR energy, up to >90% beyond 1.5 μm wavelength. FIG. 2 presents the reflectivity spectrum of both bare glass (FIG. 1A) and low-emissivity glass (FIG. 1B with 5 and 10 nm Ag layers) between 400 nm and 2.5 μm. The computational results presented in FIG. 2 agree with curves presented by various manufacturers.

Spectral integrations were compared to the 10 nm Ag, low-∈ baseline to determine the net advantage of MTM window glass designs. The present inventors found that the opportunity for improvement lies within the near-IR band, which contains nearly 50% of all solar energy, yet virtually none of that emitted from the interior of heated structures. The reflection of near-IR energy is therefore desirable only during periods of warm external temperature, when energy is used to cool the interior of the structure. During periods of cold external temperature, commercial low-∈ window glass reflects near-IR energy wastefully to the environment. Window glass with the ability to modify its emissive and reflective properties based on external temperature can make use of this wasted solar energy during colder conditions, thereby boosting energy efficiency by tapping into a fraction of the spectrum containing over 400 Watts/m2.

Variable emissivity metamaterial window glass has been conceived and developed to overcome the problems in the prior art. The reflection of near-IR energy can be modified through the unique, near-field properties of nanostructured silver. FIGS. 3A and 3B are schematics of one MTM glass concept in configurations causing either high near-IR reflectivity or high near-IR absorptivity. The MTM glass makes use of the plasmonic coupling mechanism demonstrated by nano- and micro-sized Ag objects. When two Ag structures are separated by a sufficient distance—typically larger than the characteristic wavelength of interest—no coupling effect will exist. However, if the Ag structures are moved within a few tens of nanometers of each other, a surface plasmon resonance will be achieved, generating intense local fields, sometimes referred to as anomalous absorption. It is this structure that is used here to capture the energy in the near-IR portion of the solar spectrum during periods of cold temperature. On a hot, sunny day, the present invention uses either separation of the Ag structures or rotation of the MTM assembly, producing standard low-emissivity reflection performance. By rotation of the MTM assembly, the present invention includes and is not limited to rotating, e.g., the entire window panel, portions of a window panel, French blinds, glass slits, or other mechanisms that would change the face or surface that is first contacted. FIG. 3A shows a “unit cell” of the MTM glass segment of the present invention, in which the standard low-emissivity glass is represented by the substrate upon which a 10 nm Ag layer is deposited. This is a high-efficiency, commercial design. An additional film—designated the MTM layer—containing discrete 100 nm×100 nm Ag squares of thickness 10 nm and 200 nm period is modeled and is separated from the Ag surface by a distance of 30 nm. FIG. 3B shows the configuration with the MTM layer raised 750 nm above the Ag surface (the dielectric film in which the Ag MTM squares would be embedded is not shown for clarity).

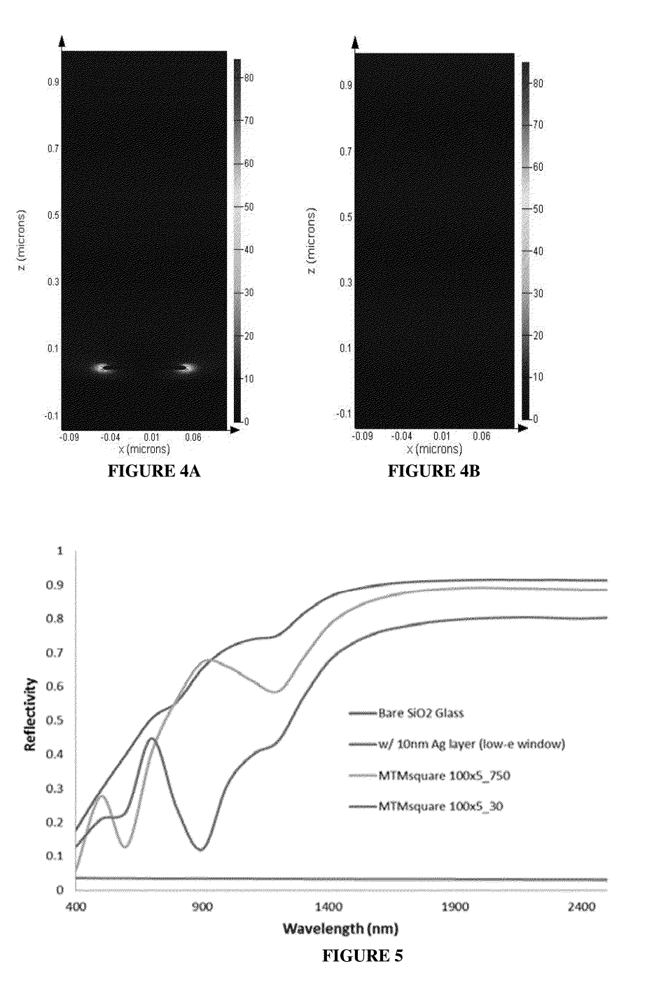

Next, 3-D FDTD simulations were performed for both cases. Electric field profiles are shown in FIGS. 4A and 4B for the discrete near-IR wavelength of 800 nm. It is clear that localized coupling exists in case (4A), where the MTM layer is in close proximity to the Ag surface. The local electromagnetic field is enhanced by more than a factor of 80. In the case shown in FIG. 4B, the structures demonstrated a lack of coupling, and hence absorption, when the MTM layer is moved only a short distance away. There is very little field enhancement, and the reflectivity is comparable to the case of a traditional low-emissivity window.

Simulations were performed for wavelengths between 400 nm and 2.5 μm to determine the effect of MTM layer presence and transition over the relevant portion(s) of the solar spectrum. These results are presented in FIG. 5, indicating that the presence of the MTM layer only 30 nm from the base Ag layer dramatically reduces the reflectivity in the near-IR between 700-1000 nm. This additional energy would now be absorbed and convected to the interior, reducing the heating demand of the structure in which the windows are installed.

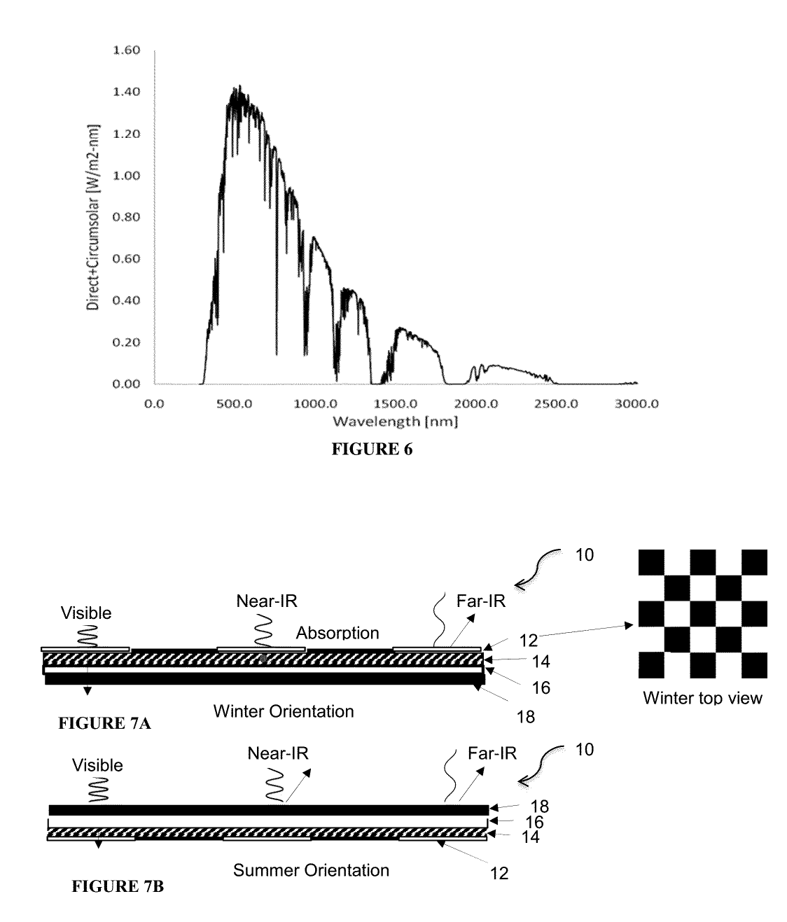

The net energy effect of an MTM glass design must be calculated by integrating the product of the reflectivity and the solar intensity over the wavelength range of interest. The ASTM Reference Spectra (1.5 Air Mass) Direct plus Circumsolar data is used here, shown in FIG. 6.

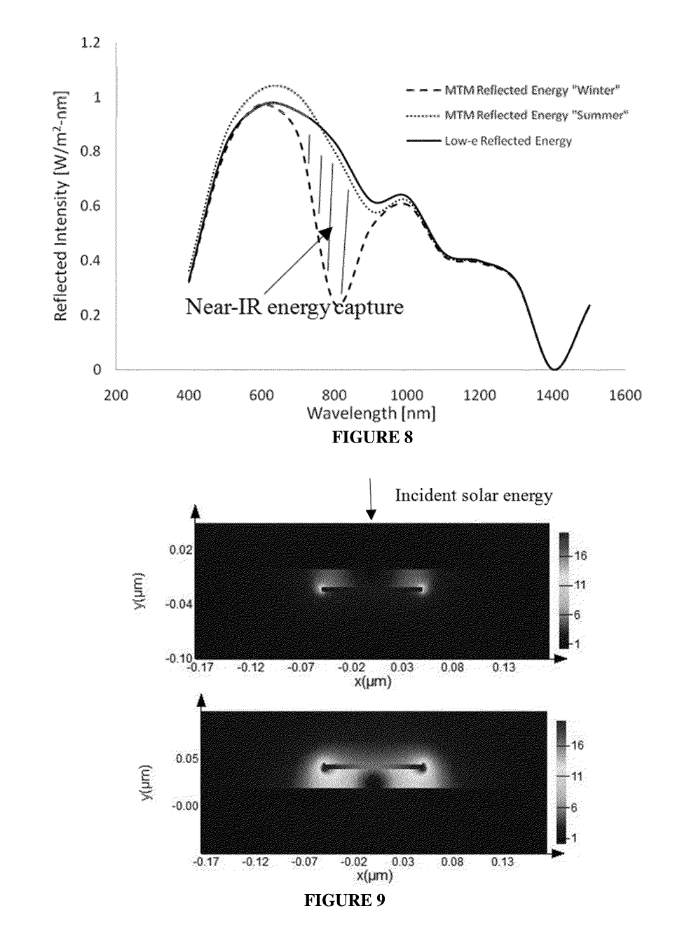

One example of an MTM glass 10 design is presented in FIGS. 7A and 7B, made with a 20 nm thick Ag base layer 16 on glass 18, followed by dielectric layer 14 of width 20 nm, followed by a square-patterned Ag layer 12 (5.0 nm thick), with square side dimension 100 nm and period of 350 nm. Two options exist for transition from winter (FIG. 7A) to summer configuration (FIG. 7B): rotating the window glass to present the opposite side to the exterior, or moving the Ag layers apart by a distance on the order of microns. FIG. 8 illustrates the rotation of the MTM glass from winter to summer configuration. It should also be noted that climates with cold weather year-round may simply maintain a static configuration, which maximizes the sustainability benefit of MTM window glass without any transition. Conversely, the present invention can be used in areas with high temperatures to lessen the HVAC load. FIG. 8 plots the product of this spectrum and the reflectivity values of baseline low-∈ glass, along with that of one MTM window glass design in a “summer” configuration, and MTM window glass in a “winter” configuration, for wavelength values between, e.g., 400 and 1500 nm.

FIG. 8 predicts very comparable performance of low-e and MTM glass in the summer configuration. With rotation to winter configuration, however, simulations predict a dramatic absorption/transmission effect in the near-IR band. Integration of the curves reveals 94.6 W/m2 captured by the MTM glass relative to the commercial low-∈ window, for the design specified. FIG. 9 gives the electromagnetic field distribution in the vicinity of the glass for both winter and summer orientations at λ=800 nm, showing the interaction in the solar near-IR range with the MTM layers.

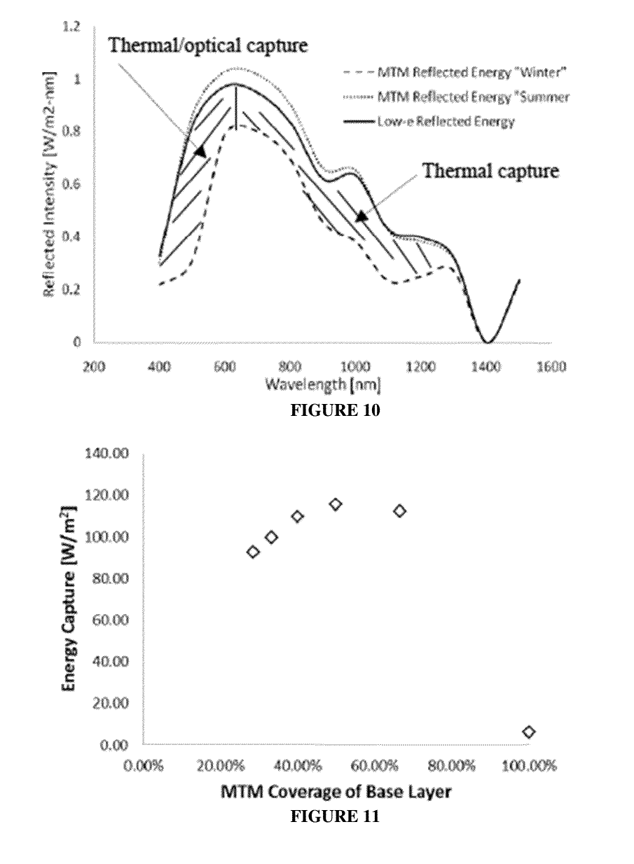

Simulations also imply that a tinting effect may occur in some designs due to increased absorption in the optical range, primarily at the red end of the spectrum. Therefore, an aesthetic trade exists in which the amount of change in optical transmission counters the amount of change in near-IR reflection. The metric is in part subjective, but a reasonable transmission threshold can be applied, while maximizing near-IR absorption within this constraint. FIG. 10 presents the reflected spectral intensity for an MTM design with a 20 nm thick Ag base layer on glass, followed by dielectric layer of width 100 nm, followed by a square-patterned Ag layer 5 nm thick, with square side dimension 200 nm and period of 400 nm. Again, a dramatic effect is shown with rotation from summer to winter configurations and is consistent through the optical and near-infrared. The enhanced optical absorption greatly contributes to the thermal efficiency, boosting the energy capture to 214.6 W/m², but reducing optical transmission to approximately 30%, not unlike a pair of sunglasses. FIGS. 8 and 10 combined illustrate the sensitivity of the radiative properties to small changes in design. In this case, only the distance of separation between base and MTM Ag layers created the strong enhancement in optical absorption, implying the possibility of commercial products, which offer an entire range of adaptably efficient glass per the situational need.

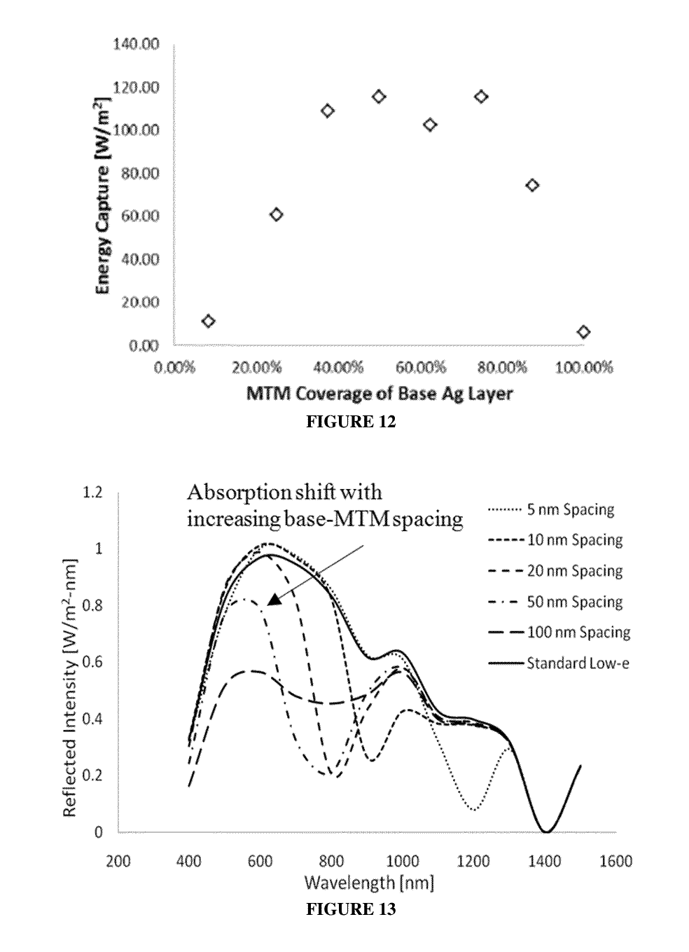

This sensitivity requires an understanding of the effect as a function of relevant parameters, including MTM layer size, period, and spacing. FIG. 11 presents a set of points predicting the energy capture of an MTM window in its winter configuration, as a function of MTM layer coverage of the Ag base layer. MTM square width and thickness are held constant at 100 nm and 5 nm, respectively. A peak exists at roughly 50% coverage, with the design accessing nearly 120 W/m² of formerly reflected energy. Likewise, when holding the MTM period constant at 200 nm while varying MTM square width, a similar trend is observed in FIG. 12, though with a notable dip at 50% coverage. Depending on the optical properties desired, however, it may be preferable to shift the design off-peak to allow for increased transmission in the range of λ=400-700 nm.

The spacing between the MTM and base Ag layers represents both a way to transition between winter and summer configurations and a design point. FIG. 13 presents the results of simulations revealing the strong spectral dependence on this parameter. As the MTM layer is moved away from the base Ag layer, the enhanced absorption shifts from the near-IR into the visible range, with the total energy absorbed generally increasing. FIG. 13 presents a very specific mechanism for tuning not only total energy absorbed, but the optical quality of the resultant window glass, including tint and coloration. FIG. 13 presents the results of simulations revealing the strong spectral dependence on this parameter, considering normal incidence. Applications of this mechanism extend beyond improvements in energy efficiency to decorative and functional products such as stained glass and sunglasses.

A final important parameter of interest is the response of MTM glass to various incident angles, as the sun sweeps through the sky. High-fidelity simulations predict insensitivity through a cone angle of 90 degrees (−45 to 45 degree incident angles), accounting for virtually all expected irradiation during the day. This is an important result, opening the door for practical application in, e.g., windowed or other structures.

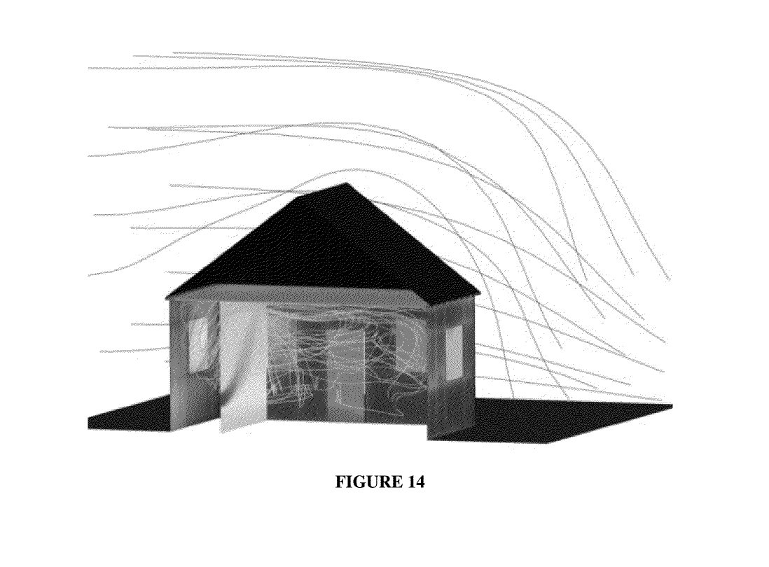

Thermal Analysis. The net energy savings as a result of using MTM window glass is dependent on its specific design configuration, as noted above, and not readily understood from the spectral reflection plots. Finite-element models were built to assess this effect on energy demands in a structure with MTM glass installed. While a large, entirely windowed structure in a predominantly cold climate would see the most dramatic savings (e.g., a skyscraper in Minneapolis), a small dwelling with conservative window coverage is shown. A portion of the structure was modeled using ANSYS CFD/thermal software as pictured in FIG. 14, wherein a small, roofed home is approximated by four fiberglass insulated walls, four 1.0 m² double-pane windows, a wooden door, an insulated ceiling, attic space, and roof. A cold day was simulated by applying a 1.0 m/s, 0° F. boundary condition across the home, while supplying heated air through an interior vent to maintain an average internal temperature of 70° F. The Navier-Stokes and energy equations were solved in all fluid domains, and the energy equation in all solid domains, converging on a steady-state solution of the notional environment.

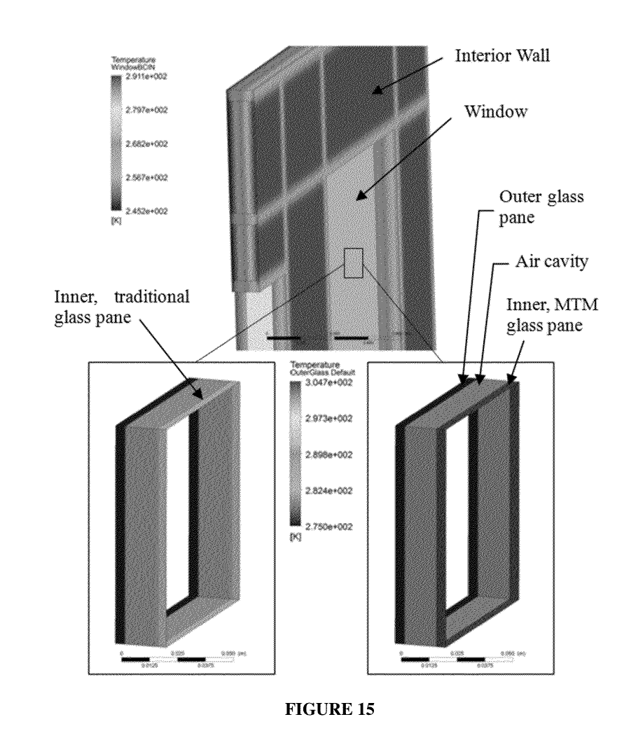

Approximately 70% of the heat loss to the environment is predicted to occur through the windows and door using standard, double-pane windows. Simulations predict a heating demand of 376 Watts at the listed conditions (noting that a small, well-insulated, “half-room” is the extent of the model domain). During periods of sunlight, energy absorbed by the MTM window can reduce this demand. FIG. 15 presents the temperature distribution in the double-pane window with a standard design, and with the MTM glass design with performance specified in FIG. 8. The energy absorbed by the MTM glass raises the temperature of the inner pane by 9° C., up to 304.6 K (98° F.). Convecting this heat directly to the outside is a concern with single-pane windows, however, FIG. 15 shows that a typical double-pane window with a 16.0 mm thick air cavity keeps most of the energy at the inner boundary where it can be convected to the structure's interior. Thermal radiation in the cavity was not considered in the model.

Depending on the orientation of the house to the sun, simulations predict a reduction in demand between 19-38% during periods of sunlight. Therefore, considering a full diurnal cycle, the installation of MTM window glass is predicted to reduce the total heating demand of the structure by ˜6-12% on days with sun. These values are based on largely conservative assumptions (i.e. the MTM design used is optically transparent with moderate absorption) and are offered for the single case specified. A large structure with severe heating demands may expect to reduce this load by an even greater margin.

Design options for ultra-high efficiency metamaterial window glass are presented. Commercial, low-emissivity window design utilizing Ag thin-films is extended to include nanopatterned Ag layers assembled into a metamaterial stack. A significant net sustainability effect is derived from the MTM window glass's reflection of most near-infrared energy in a “summer” configuration, while capturing a large portion of this near-IR energy in a “winter” configuration through non-linear radiative coupling. A combination of electromagnetic and CFD/thermal simulations predicts that installation of MTM window glass will enhance the energy efficiency of any windowed structure with heating requirements.

It is contemplated that any embodiment discussed in this specification can be implemented with respect to any method, kit, reagent, or composition of the invention, and vice versa. Furthermore, compositions of the invention can be used to achieve methods of the invention.

It will be understood that particular embodiments described herein are shown by way of illustration and not as limitations of the invention. The principal features of this invention can be employed in various embodiments without departing from the scope of the invention. Those skilled in the art will recognize, or be able to ascertain using no more than routine experimentation, numerous equivalents to the specific procedures described herein. Such equivalents are considered to be within the scope of this invention and are covered by the claims.

All publications and patent applications mentioned in the specification are indicative of the level of skill of those skilled in the art to which this invention pertains. All publications and patent applications are herein incorporated by reference to the same extent as if each individual publication or patent application was specifically and individually indicated to be incorporated by reference.

The use of the word “a” or “an” when used in conjunction with the term “comprising” in the claims and/or the specification may mean “one,” but it is also consistent with the meaning of “one or more,” “at least one,” and “one or more than one.” The use of the term “or” in the claims is used to mean “and/or” unless explicitly indicated to refer to alternatives only or the alternatives are mutually exclusive, although the disclosure supports a definition that refers to only alternatives and “and/or.” Throughout this application, the term “about” is used to indicate that a value includes the inherent variation of error for the device, the method being employed to determine the value, or the variation that exists among the study subjects.

As used in this specification and claim(s), the words “comprising” (and any form of comprising, such as “comprise” and “comprises”), “having” (and any form of having, such as “have” and “has”), “including” (and any form of including, such as “includes” and “include”) or “containing” (and any form of containing, such as “contains” and “contain”) are inclusive or open-ended and do not exclude additional, unrecited elements or method steps. In embodiments of any of the compositions and methods provided herein, “comprising” may be replaced with “consisting essentially of” or “consisting of”. As used herein, the phrase “consisting essentially of” requires the specified integer(s) or steps as well as those that do not materially affect the character or function of the claimed invention. As used herein, the term “consisting” is used to indicate the presence of the recited integer (e.g., a feature, an element, a characteristic, a property, a method/process step or a limitation) or group of integers (e.g., feature(s), element(s), characteristic(s), propertie(s), method/process steps or limitation(s)) only.

The term “or combinations thereof” as used herein refers to all permutations and combinations of the listed items preceding the term. For example, “A, B, C, or combinations thereof” is intended to include at least one of: A, B, C, AB, AC, BC, or ABC, and if order is important in a particular context, also BA, CA, CB, CBA, BCA, ACB, BAC, or CAB. Continuing with this example, expressly included are combinations that contain repeats of one or more item or term, such as BB, AAA, AB, BBC, AAABCCCC, CBBAAA, CABABB, and so forth. The skilled artisan will understand that typically there is no limit on the number of items or terms in any combination, unless otherwise apparent from the context.

As used herein, words of approximation such as, without limitation, “about”, “substantial” or “substantially” refers to a condition that when so modified is understood to not necessarily be absolute or perfect but would be considered close enough to those of ordinary skill in the art to warrant designating the condition as being present. The extent to which the description may vary will depend on how great a change can be instituted and still have one of ordinary skilled in the art recognize the modified feature as still having the required characteristics and capabilities of the unmodified feature. In general, but subject to the preceding discussion, a numerical value herein that is modified by a word of approximation such as “about” may vary from the stated value by at least ±1, 2, 3, 4, 5, 6, 7, 10, 12 or 15%.

All of the compositions and/or methods disclosed and claimed herein can be made and executed without undue experimentation in light of the present disclosure. While the compositions and methods of this invention have been described in terms of preferred embodiments, it will be apparent to those of skill in the art that variations may be applied to the compositions and/or methods and in the steps or in the sequence of steps of the method described herein without departing from the concept, spirit and scope of the invention. All such similar substitutes and modifications apparent to those skilled in the art are deemed to be within the spirit, scope and concept of the invention as defined by the appended claims.

What is claimed is:

1. A variable emissivity metamaterial comprising:
a substrate;
a surface plasmon-generating layer on the substrate;
a dielectric layer on the surface plasmon-generating layer; and
one or more arrays of nanostructured objects deposited on the dielectric layer, wherein the objects comprise a material that has near-IR reflectivity and near-IR absorptivity and the one or more arrays are positioned between 5 and 750 nM from the substrate.

2. The metamaterial of claim 1, wherein the objects are triangular, square, rectangular, pentagonal, hexagonal, heptagonal, octagonal, polygonal, trapezoid, striated, lines, irregular, circular, conical, or oval.

3. The metamaterial of claim 1, wherein the material is at least one of silver, copper, gold, tungsten, titanium, tantalum, aluminum, or platinum.

4. The metamaterial of claim 1, wherein the array is regular, periodic, irregular, or variable.

5. The metamaterial of claim 1, wherein the array comprises one or more unit cells of objects.

6. The metamaterial of claim 1, wherein the array is regular, checkerboard, irregular, or variable.

7. The metamaterial of claim 1, wherein the variable emissivity metamaterial is disposed on one or more surfaces of the substrate.

8. The metamaterial of claim 1, wherein the substrate is at least one of glass, fused silica glass, soda-lime-silica glass, borosilicate glass, lead-oxide glass, aluminosilicate glass, oxide glass, ceramic, polarized glass, plastic, polycarbonate, polyacrylate, cellulose acetate, butyrate, nylon, polyolefin, polyester, polyurethane, para-aramid synthetic fiber, or mixtures thereof.

9. The metamaterial of claim 1, further comprising a passivation layer disposed on the array.

10. The metamaterial of claim 1, wherein the one or more arrays are printed on a film, paint, or coating and the film paint, or coating is attached to the substrate.

11. The metamaterial of claim 1, wherein the array is positioned at 5, 6, 7, 8, 9, 10, 11, 12, 13, 14, 15, 16, 17, 18, 19, 20, 21, 22, 23, 24, 25, 26, 27, 28, 29, 30, 35, 40, 45, 50, 60, 70, 75, 80, 90, 100, 125, 150, 200, 250, 300, 350, 400, 450, 500, 550, 600, 650, or 700 nm from the substrate.

12. The metamaterial of claim 1, wherein the array is embedded in a film or coating.

13. The metamaterial of claim 1, wherein the array is separated from the substrate by a dielectric.

14. A method of variable emissivity metamaterial comprising:
obtaining a substrate;
depositing a surface plasmon-generating layer on the substrate;
placing a dielectric layer on the surface plasmon-generating layer; and
placing on the dielectric layer one or more arrays of nanostructured objects at between 5 and 750 nM from the dielectric layer, wherein the objects comprise a material that has near-IR reflectivity and near-IR absorptivity.

15. The method of claim 14, wherein the objects are triangular, square, rectangular, pentagonal, hexagonal, heptagonal, octagonal, polygonal, trapezoid, striated, lines, irregular, circular, conical, or oval.

16. The method of claim 14, wherein the material is at least one of silver, copper, gold, tungsten, titanium, tantalum, aluminum, or platinum.

17. The method of claim 14, wherein the array is regular, checkerboard, irregular, or variable.

18. The method of claim 14, wherein the array comprises one or more unit cells of objects.

19. The method of claim 14, wherein the array is regular, periodic, irregular, or variable.

20. The method of claim 14, wherein the variable emissivity metamaterial is disposed on one or more surfaces of the substrate.

21. The method of claim 14, wherein the substrate is at least one of glass, fused silica glass, soda-lime-silica glass, borosilicate glass, lead-oxide glass, aluminosilicate glass, oxide glass, ceramic, polarized glass, plastic, polycarbonate, polyacrylate, cellulose acetate, butyrate, nylon, polyolefin, polyester, polyurethane, para-aramid synthetic fiber, or mixtures thereof.

22. The method of claim 14, further comprising a passivation layer disposed on the array.

23. The method of claim 14, wherein the one or more arrays are printed on a film, paint, or coating and the film paint, or coating is attached to the substrate.

24. The method of claim 14, further comprising the step of optimizing the array and distance between the array and the substrate for at least one of total energy absorbed, optical quality, tint or coloration.

25. The method of claim 14, wherein the array is positioned at 5, 6, 7, 8, 9, 10, 11, 12, 13, 14, 15, 16, 17, 18, 19, 20, 21, 22, 23, 24, 25, 26, 27, 28, 29, 30, 35, 40, 45, 50, 60, 70, 75, 80, 90, 100, 125, 150, 200, 250, 300, 350, 400, 450, 500, 550, 600, 650, or 700 nm from the substrate.

26. The method of claim 14, further comprising the step of embedding the one or more arrays in a film or coating.

27. A variable emissivity metamaterial film comprising an array of nanostructured objects, wherein the objects comprise a material that has near-IR reflectivity and near-IR absorptivity.

28. The variable emissivity metamaterial film of claim 27, wherein the film is provided in rolls to retrofit existing substrates.

29. A window comprising:
a glass substrate on a reversible frame;
a surface plasmon-generating layer on the substrate;
a dielectric layer on the surface plasmon-generating layer; and
an array of nanostructured objects deposited on the dielectric layer, wherein the objects comprise a material that has near-IR reflectivity and near-IR absorptivity.

30. A coating comprising an array of nanostructured objects deposited on a dielectric layer, wherein the objects comprise a material that has near-IR reflectivity and near-IR absorptivity.
